(19) United States
(12) Patent Application Publication
(10) Pub. No.: US 2011/0068073 A1
(43) Pub. Date: Mar. 24, 2011

(54) Tool-less Metal Filler Panel for a Data Rack

(76) Inventor: John Michael Hervey, Aptos, CA (US)

(21) Appl. No.: 12/877,395

(22) Filed: Sep. 8, 2010

Related U.S. Application Data
(60) Provisional application No. 61/241,104, filed on Sep. 10, 2009.

(51) Int. Cl. H05K 7/16; H05K 7/18

(52) U.S. Cl. 211/169; 211/41.12

(57) ABSTRACT

A tool-less metal filler panel for a data rack includes: a main panel; a slide latch on the main panel; and a plurality of pivot legs on the main panel. The pivot legs retain the main panel against the data rack.

### BACKGROUND

A great many rack-mount electrical and electronic cabinets are in use and manufactured and sold every year. In these cabinets filler panels are a common and necessary component to be engaged to spaced-apart vertical rails in such cabinets. In the current art such panels typically require tools for engagement. There is a clear need for tool-less filler panels.

### SUMMARY OF THE INVENTION

In one embodiment of the present invention a filler panel for a data rack is provided, having a metal body, a slide latch at one end, and pivot legs at each end for engaging openings in vertical rails of a data rack. In various embodiment the filler panel may have varying dimensions, and may be made of various materials. Metal is preferable in many embodiments.

### BRIEF DESCRIPTION OF THE DRAWINGS

FIG. 1 is an illustration of a tool-less metal filler panel shown attached between two vertical data rack rails in an embodiment of the present invention.

FIG. 2 illustrates the tool-less filler panel of FIG. 1 without the vertical rails.

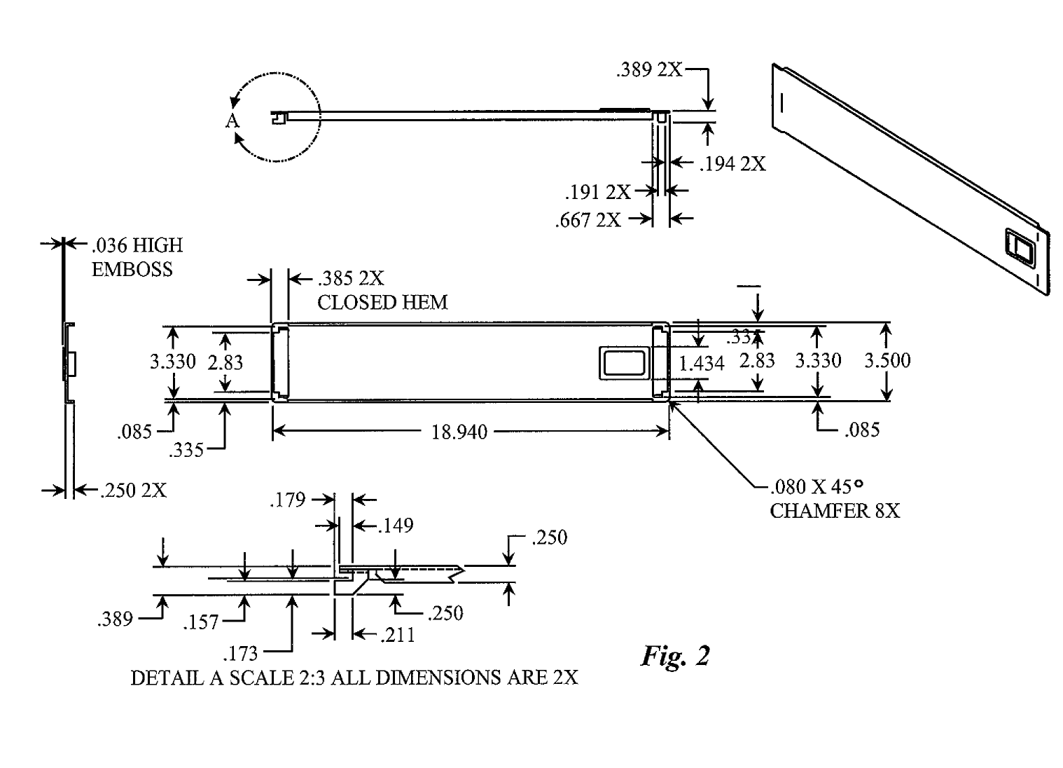

FIG. 3 is an illustration of fastening and sealing elements and methods in an alternative embodiment of the invention.

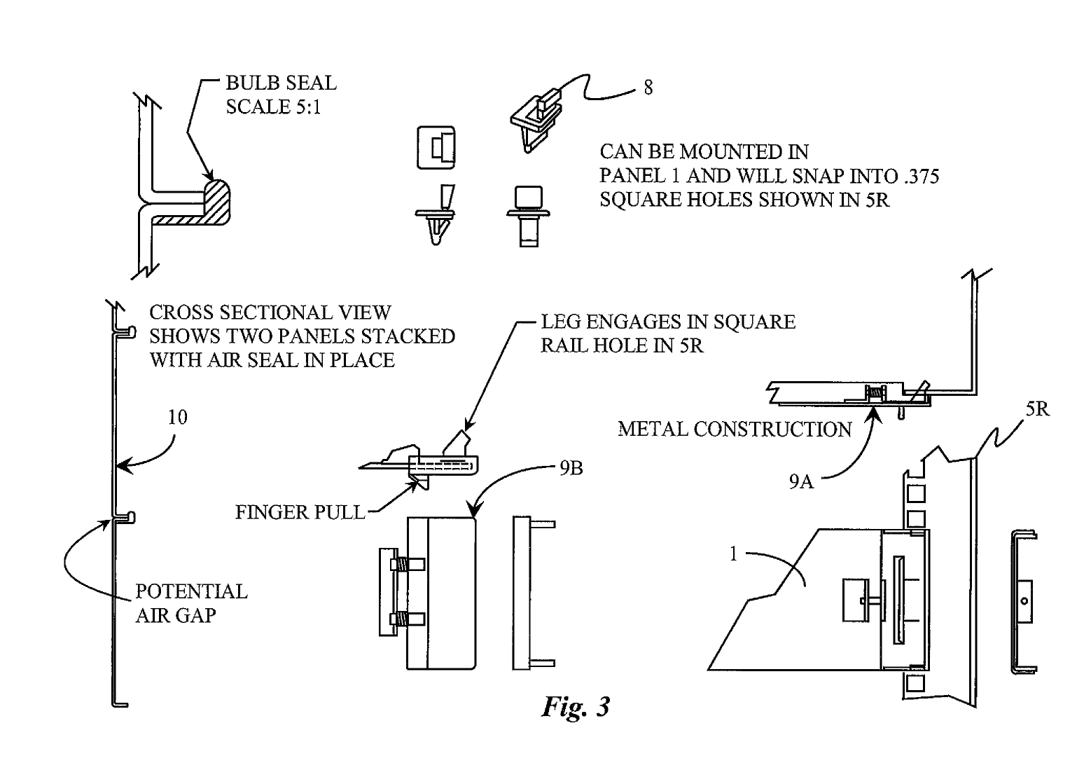

### DETAILED DESCRIPTION OF THE INVENTION

In the description to follow, and in the drawings, the following element numbers are used associated with physical elements: (1) Main body of panel; (2) Sliding latch; (3) Leg (pivot) bracket; (4) Control bracket; (5) Rails, L & R (ref only); (6) Top flange; (7) Bottom flange; (8) Snap clip (molded); (9) End assembly (spring loaded); and (10) Cross section view for reference only.

The following detailed description is of the best currently contemplated mode of carrying out exemplary embodiments of the invention. The description is not to be taken in a limiting sense, but is made to illustrate and teach examples of the invention. The scope of the invention is best defined by the appended claims.

Broadly, an embodiment of the present invention generally provides a tool-less metal filler panel (1) also known as a “blanking panel” to block-off an open area in a server data rack.

In the current art too many fasteners (screws, nuts, and/or special type fasteners) are required to install filler panels. This includes panels that require tools and/or the tool-less type of filler panel that does not require a tool to install (for example, with a screw driver). The tool-less type that are currently available require twice as many fasteners than this design aka Fasnap™ filler panels.

Also, existing filler panels do not fit/work well because the “out of spec” dimensions on the enclosure they are being attached to i.e., if the rail 5L & 5R (17.750) or the rail hole dimension of 18.312 is out of spec (standard EIA 310-D), the filler panel will not line up and is useless. Existing filler panels leak air through small gaps when they are mounted in vertical rows.

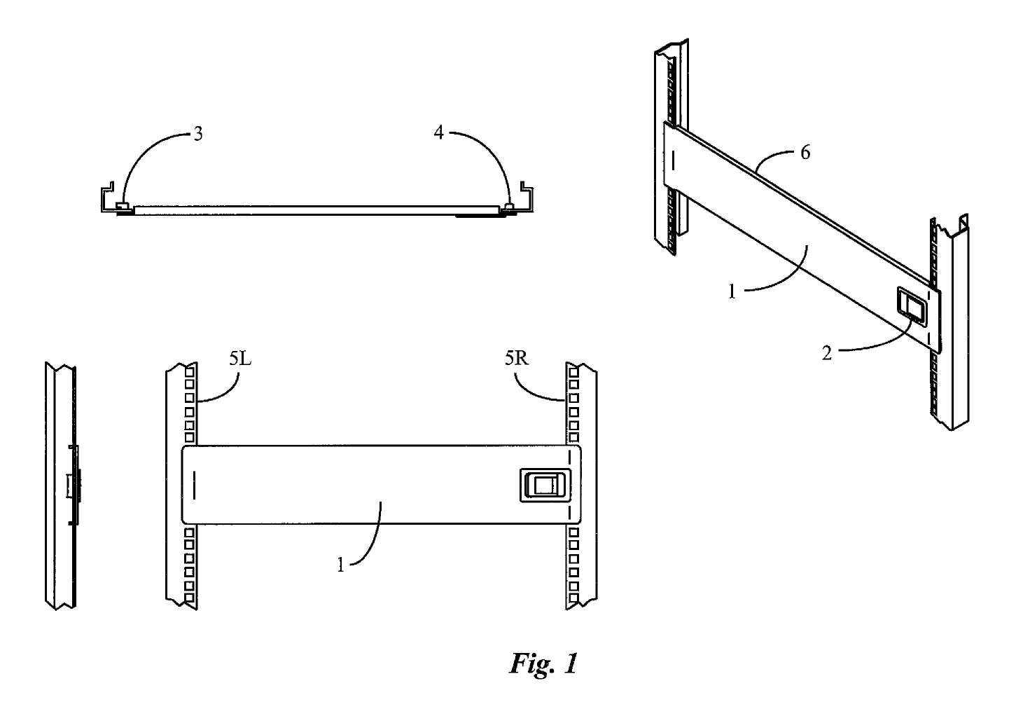

In an embodiment of the present invention, the filler panel (1) utilizes existing standardized holes in the rack rails 5L & 5R (FIG. 1) that they attach to. The panel attaches by inserting legs (3) (formed metal tabs) through the rail holes on either the left or right side. The final assembly is performed by closing the opposite end of the panel; slipping the control bracket (4) into position; which locks in place to the rail 5L or 5R, with a slide latch (2). It thereby reduces the amount of required fasteners and/or tools required for installation. It simplifies installation. A special slide type latch 2 is used to grip onto the backside of the rail 5L or 5R. The latch is designed to work even if the rail location is not located properly or out of spec. The latch accommodates this situation by latch travel up to 0.250 (¼ inch). The rail to rail opening as specified in the EIA-310D standard is 17.75. Racks that are distorted fall within +/−.060 of 17.75. By using a slide latch with a 0.250 range in motion compensates for 17.75 being “out of spec”; the design essentially makes the filler panel a good solution for all racks. The filler panel (1) has flanges (6) & (7) formed into it so that when it is mounted, it closes the horizontal gap/seam; when flange (7) of the adjacent part rests on flange (6).

To make an embodiment of the present invention, the main body (1) of the filler panel is fabricated out of 0.047 thick mild steel. It can be made thicker or thinner. It could also be injection molded using various types of thermo plastic compounds such as ABS. The slide latch (2) is a molded component; but it could be a machined part. It can also be eliminated by using (8) (snap clip) or (9) (spring loaded end assembly). The pivot legs (3) are formed/fabricated into the main panel (1). The pivot legs guide the panel into the correct mounted position by guiding them through existing rail holes in 5L or 5R. The pivot legs also act as a stop and help to tension the panel into place. When installing, the panel pivots or turns about the legs (3). They can also be molded into the main panel (1). The control bracket 4 is also fabricated/formed out of the main body (1). The bracket (4) (2 places) guides the panel into place before the slide latch (2) is snapped into place. The control bracket (4) can also be molded into the main panel. The vertical rails 5L & 5R areas are for reference only. They are shown to clarify the relation ship of the panel (1), sliding latch (2), pivot legs (3), and control legs (4) to the rails 5L & 5R. The top flange (6) and bottom flange (7) are formed into the main panel (1). The purpose of these flanges is to provide strength and rigidity to the panel. The panel (1) can be mounted by itself on the rails 5L & 5R. The panel can also be mounted one after the other, or several panels high (stacked) to fill a large opening. When the panels are “stacked”, the lower flange (6) rests/seals on the upper flange (7) of the adjacent panel. See (10) cross sectional view of stacked panels (1). The seal created by joining adjacent flanges (6) & (7) may also be achieved by roll forming, conventional forming, or molding. A sort of tongue and groove profile can be manufactured into this joint; improving the seal and panel rigidity through the related stress hardening, while adding a unique appearance.

An embodiment includes the leg bracket (3), which eliminates the need for fasteners & screw driver. Also included are the control bracket, the upper flange (6), and the lower flange (7).

An embodiment includes the slide latch (2), which eliminates the need for fasteners (screws & cage nuts) and a screw driver. It could be eliminated by using the snap clip (8) or the spring loaded end assembly (9).

In an embodiment, the main body of the panel 1, the pivot legs (3), the control bracket (4), the upper flange (6), & the lower flange (7) are formed/fabricated out of one piece of sheet steel. Although they have separate functions, they are features of one piece. The slide latch (2) is assembled into a 1×2 inch cutout in the panel 1 after the panel 1 is painted. (1), (3), (4), (6), & (7) could be a one piece plastic molded part that the slide latch (2) could assemble to. Or, the latch (2) could be eliminated and replace with either the snap clip (8), or the spring loaded end assembly (9). Both (8) & (9) could be machined, but molding is the current method of producing (8) & (9).

To use an embodiment, an installer simply slips the two pivot legs (3) into the chosen rail holes 5L or 5R. The panel is then pivoted into place by guiding the control brackets (4) into the correct rail 5L or 5R. When the panel (1) becomes nearly flush with the rail 5L or 5R, the sliding latch(2) locks the panels in place.

Embodiments of the invention can either be fabricated from sheet steel, or molded with plastic such as PC ABS. All of the features can be molded into the main body (1).

In another embodiment, the same design can simplify panel assembly on various products

In an embodiment, the latch mechanism(2) can be integrated into a secondary spring loaded component (end assembly 9) adding more travel could eliminate latch by having leg bracket on both sides and panel would be a two piece device with a spring actuated feature to take the place of a latch. In essence the panel would be able to collapse and expand

Another method would be to replace the slide latch with a snap-action clip (8) (either metal or plastic) that clips onto the rail; or it can snap into rail holes (0.375 squares).

Computer servers are installed in racks. In order to fill space and control air flow; filler panels are installed wherever there is an unused area or opening. A person installs this product by inserting the legs (3) in the rails holes 5L or 5R, then finishing by closing the sliding latch 2 end of the panel 1. This usually takes 4-5 seconds.

Other embodiments may apply to any application to ease installation by eliminating the need for hardware and tools (screw/nuts/screwdrivers)

Embodiments of this design may reduce the amount of required fasteners. It can work on several types of panel applications and installations where tools are not required for installation, and a tight seal is important.

An embodiment, which may be called “Fasnap™,” is a filler panel that is tool-less, has few fasteners, may be inexpensive to manufacture, and easier to install. It works (mounts) even if the rack is out of spec. It also prevents leaks thereby reducing energy costs in data centers. Current filler panels either have to be fastened with (2) or more fasteners (screws attached to cage-nuts); which sometimes fail due to distortion in the cabinet (the fasteners do not line up) with the holes that they are being attached to. They take more time to install. You also need a screwdriver to attach. If one of the fasteners fails, the panel will not work. There are basically two types of tool-less panels.

The first is the aforementioned style that has to line up with cabinet holes 5L 5R to work.

The second style does not utilize the rail feature (standard square rail holes) that the filler panel does. It does not have as much forgiveness (dimensional range) as the filler design, should the cabinet be distorted or out of specification. Also, it is a plastic molded style and protrudes too much above the mounting surface, eating into valuable space (whereby filler panels are flat & low profile)

Nearly every filler panel on the market leaks air. Fasnap™ filler panels may stop the air leak by mating two surfaces (6) & (7); closing the gap between panels.

Embodiments may eliminate the need for additional fasteners (¼ turn type plastic/metal screws, or latches). In addition, and although simple, the sealing of the gap between panels by mating adjacent flanges is not produced by any other manufacturer yet! With skyrocketing energy costs it has become critical to stop the leak between panels-hence, existing products have a molded plastic panel whose flanges are not quite 90 degrees and interfere-creating a seal.

Embodiments eliminate fasteners via this type of design. Existing products use solid plastic with protrusions that allow the panel to engage the inside opening of the rails. These products do not produce a metal type that takes advantage of the square rail holes by forming an interlocking (pivoting) leg such as with embodiments of the present invention.

It should be understood, of course, that the foregoing relates to exemplary embodiments of the invention and that modifications may be made without departing from the spirit and scope of the invention as set forth in the following claims.

We claim:

1. A device for a data rack, comprising:
a main panel;
a slide latch on the main panel; and
a plurality of pivot legs on the main panel;
wherein the pivot legs retain the main panel against the data rack.

2. The device of claim 1, wherein there is no gap between panels.

3. The device of claim 1, wherein the main panel is fastened to the slide latch by the plurality of pivot legs.
